(19) United States
(12) Patent Application Publication
(10) Pub. No.: US 2022/0418139 A1
(43) Pub. Date: Dec. 29, 2022

(54) ENGAGING DRIVING STRUCTURE

(71) Applicant: FIVETECH TECHNOLOGY INC., New Taipei City (TW)

(72) Inventors: TING-JUI WANG, New Taipei City (TW); CHIA-CHING LIAO, New Taipei City (TW)

(21) Appl. No.: 17/732,572

(22) Filed: Apr. 29, 2022

(30) Foreign Application Priority Data
Jun. 24, 2021 (TW) 110123155

(51) Int. Cl. H05K 7/14; G06F 1/18; G11B 5/48

(52) U.S. Cl. CPC H05K 7/1402; G06F 1/186; G11B 5/4853; G11B 2220/2516

(57) ABSTRACT

Provided is an engaging driving structure having a first driving fastener, a second driving fastener and a linking unit. The second driving fastener is disposed beside the first driving fastener. The linking unit is disposed between the first driving fastener and the second driving fastener and adapted to movably connect the first driving fastener and the second driving fastener. Therefore, the engaging driving structure is easy to use, labor-saving, and convenient.

### CROSS-REFERENCE TO RELATED APPLICATION

This non-provisional application claims priority under 35 U.S.C. § 119(a) on Patent Application No(s). 110123155 filed in Taiwan, R.O.C. on Jun. 24, 2021, the entire contents of which are hereby incorporated by reference.

### BACKGROUND OF THE INVENTION

### 1. Field of the Invention

The present disclosure relates to engaging driving structures, and in particular to an engaging driving structure which is easy to use, labor-saving, and convenient.

### 2. Description of the Related Art

Conventional frames each come with an unloading mechanism (also known as releasing mechanism). The unloading mechanism enables a hard disk drive or circuit board to separate from a port disposed in the frame. The unloading mechanism is rotated by a user in order to push and move the hard disk drive or circuit board, allowing the hard disk drive or circuit board to separate from the port. However, the unloading mechanism only allows the hard disk drive or circuit board to undergo displacement of a short distance; this together with frame partition panels or adjacent devices arranged side by side render the hard disk drive or circuit board difficult and inconvenient to be taken by the user.

### BRIEF SUMMARY OF THE INVENTION

An objective of the present disclosure is to provide an engaging driving structure which is easy to use, labor-saving, and convenient.

To achieve at least the above objective, the present disclosure provides an engaging driving structure comprising a first driving fastener, a second driving fastener and a linking unit. The second driving fastener is disposed beside the first driving fastener. The linking unit is disposed between the first driving fastener and the second driving fastener and adapted to movably connect the first driving fastener and the second driving fastener.

The present disclosure further provides an engaging driving structure comprising a first driving fastener, a second driving fastener and a linking unit. The first driving fastener is movably fitted to a first object. The second driving fastener is movably fitted to the first object and adapted to abut against a second object. The linking unit is movably fitted between the first driving fastener and the second driving fastener. The first driving fastener is operated and linked to the second driving fastener to cause movement thereof, so as for the second driving fastener to abut against the second object.

In the engaging driving structure, the first driving fastener comprises a first engaging portion, an operating portion, a first fitting portion and a second fitting portion. The first engaging portion is disposed at one end of the first driving fastener.

In the engaging driving structure, the first driving fastener comprises a first engaging portion, and the first engaging portion is engaged with a first object.

In the engaging driving structure, the first driving fastener comprises a first fitting portion and a second fitting portion. The first fitting portion is movably fitted to a first object. The linking unit movably connects to the second fitting portion.

In the engaging driving structure, the first driving fastener comprises a first engaging portion and an operating portion. The first engaging portion has a first engaging member. The first engaging member is fitted to the first driving fastener through a pivotal connection member.

In the engaging driving structure, a resilient component is disposed between the first engaging member and the first driving fastener.

In the engaging driving structure, the second driving fastener comprises a second engaging portion, a third fitting portion and a fourth fitting portion. The second engaging portion is disposed at one end of the second driving fastener. The third fitting portion is disposed beside the second engaging portion. The fourth fitting portion is disposed beside the third fitting portion.

In the engaging driving structure, the second driving fastener comprises a second engaging portion, and the second engaging portion is engaged with a second object.

In the engaging driving structure, the second driving fastener comprises a third fitting portion and a fourth fitting portion. The third fitting portion is movably fitted to a first object. The linking unit movably connects to the fourth fitting portion.

In the engaging driving structure, a first connection portion is disposed at one end of the linking unit, and a second connection portion is disposed at the other end of the linking unit.

In the engaging driving structure, a first connection portion is disposed at one end of the linking unit, and the first connection portion movably connects to the first driving fastener through a first axle portion.

In the engaging driving structure, a second connection portion is disposed at one end of the linking unit, and the second connection portion movably connects to the second driving fastener through a second axle portion.

In the engaging driving structure, the first axle portion penetrates a washer, and the washer is disposed between the linking unit and the first driving fastener.

In the engaging driving structure, the second axle portion penetrates a washer, and the washer is disposed between the linking unit and the second driving fastener.

In the engaging driving structure, the first driving fastener and the second driving fastener each have an axle portion, and the axle portions are fixed to a first object to allow the first driving fastener and the second driving fastener to rotate at fixed positions.

In the engaging driving structure, the first driving fastener and the second driving fastener each have an axle portion, and the axle portions are fixed to a first object to allow the first driving fastener and the second driving fastener to rotate at fixed positions and allow the first driving fastener to drive the linking unit and the second driving fastener under a lever force.

In the engaging driving structure, the first driving fastener and the second driving fastener each have an axle portion, and the axle portions are fixed to a first object to allow the first driving fastener and the second driving fastener to rotate at fixed positions, allow the first driving fastener to drive the linking unit and the second driving fastener under a lever force, exert lever forces on a second object, and allow the first object and the second object to undergo displacement relative to each other.

In the engaging driving structure, the first object or the second object is a casing, frame, housing, box, support, PCB, motherboard, server, storage, hard disk drive, heat sink, hydrocooling device, rail, plate or disc.

In the engaging driving structure, the terminal end of the first driving fastener is movably fitted to an engaging member, and the first object comprises a clasping portion corresponding in position to the engaging member. The engaging member is engaged with the clasping portion, such that the second driving fastener and the second object abut against each other until they are positioned in place.

In the engaging driving structure, the clasping portion is a flange which extends outward from a side of the first object, and the side of the first object is positioned distal to the second object, whereas the engaging member is a hook.

In the engaging driving structure, the engaging member and the first driving fastener are movably fitted to each other by pivotal connection.

In the engaging driving structure, the first driving fastener pivotally connects to the first object, the second driving fastener to the first object, and the linking unit to the first driving fastener and the second driving fastener.

The engaging driving structure further comprises a first pivot, a second pivot, a third pivot and a fourth pivot. The first pivot pivotally connects the first driving fastener to the first object. The second pivot pivotally connects the second driving fastener to the first object. The third pivot pivotally connects the linking unit to the first driving fastener. The fourth pivot pivotally connects the linking unit to the second driving fastener.

In the engaging driving structure, the first pivot, the second pivot, the third pivot and the fourth pivot are arranged to form a rectangle and thereby allow the second driving fastener and the second object to abut against each other.

In the engaging driving structure, the first pivot, the second pivot, the third pivot and the fourth pivot are arranged to form a parallelogram, exclusive of a rectangle, and thereby allow the second driving fastener to abut against the second object.

In the engaging driving structure, an abutting-oriented acted point is located between the second driving fastener and the second object and spaced apart from the first pivot and the second pivot by a distance D1. The distance between the first pivot and the third pivot is denoted by D2. The distance between the second pivot and the fourth pivot is denoted by D2. The first driving fastener has an acting point. The distance between the acting point and the first pivot and the second pivot is denoted by D3, where 0.08<D1/D3<0.12, 0.15<D2/(D3−D2)<0.3. Thus, the applied force required by the acting point is less than the abutting force of the acted point.

In the engaging driving structure, the composite abutting force of the acted point is denoted by F1, and the applied force of the acting point is denoted by F2, where 0.012≤F1/F2≤0.036.

In the engaging driving structure, the first driving fastener comprises a movable fitting portion movably fitted to the first object and the linking unit, an operating portion parallel to the movable fitting portion, and a connection portion connected between the movable fitting portion and the operating portion.

In the engaging driving structure, the second driving fastener comprises a movable fitting body and an abutting portion connected to the movable fitting body. The movable fitting body is movably fitted to the first object and the linking unit.

In the engaging driving structure, the abutting portion has a dent portion.

In the engaging driving structure, the linking unit is a connecting rod, and two terminal ends of the linking unit are movably fitted to the first driving fastener and the second driving fastener, respectively.

Therefore, the engaging driving structure is easy to use, labor-saving, and convenient.

### BRIEF DESCRIPTION OF THE DRAWINGS

FIG. 1 is the first perspective view of an engaging driving structure according to the first embodiment of the present disclosure.

FIG. 2 is the second perspective view of the engaging driving structure according to the first embodiment of the present disclosure.

FIG. 3 is the third perspective view of the engaging driving structure according to the first embodiment of the present disclosure.

FIG. 4 is an exploded view of the engaging driving structure according to the first embodiment of the present disclosure.

FIG. 5 is the first schematic view of how to use the engaging driving structure according to the first embodiment of the present disclosure.

FIG. 6A is the second schematic view of how to use the engaging driving structure according to the first embodiment of the present disclosure.

FIG. 6B is the third schematic view of how to use the engaging driving structure according to the first embodiment of the present disclosure.

FIG. 7 is a schematic view of how to use the engaging driving structure according to the second embodiment of the present disclosure.

FIG. 8 is a schematic view of operation of a first driving fastener, second driving fastener and linking unit of the engaging driving structure according to the present disclosure.

FIG. 9 is a schematic view of operation of the second driving fastener of the engaging driving structure according to the present disclosure.

FIG. 10 is an exploded view of the engaging driving structure according to the second embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

Objectives, features, and advantages of the present disclosure are hereunder illustrated with specific embodiments, depicted with drawings, and described below.

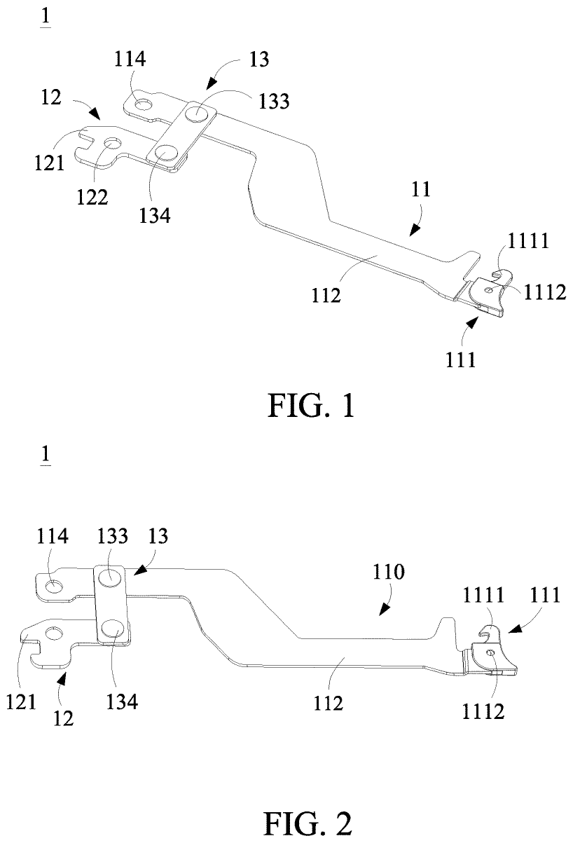

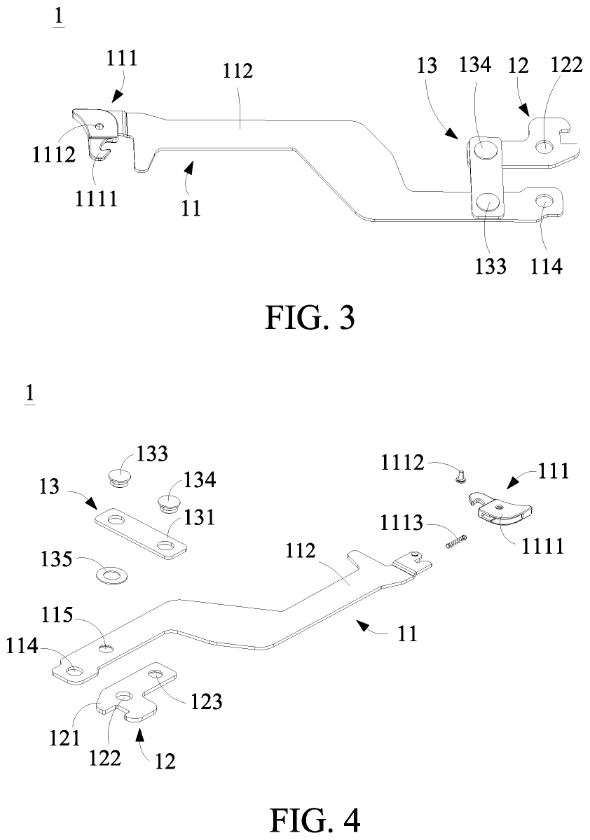

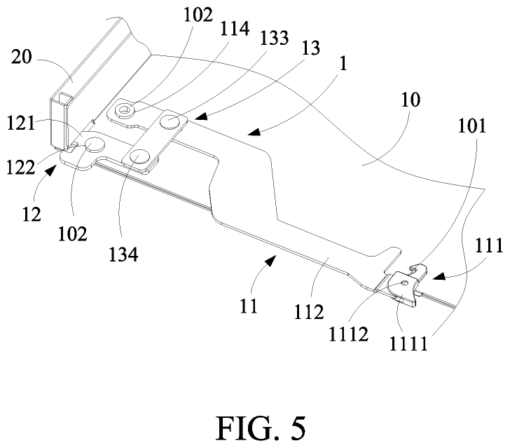

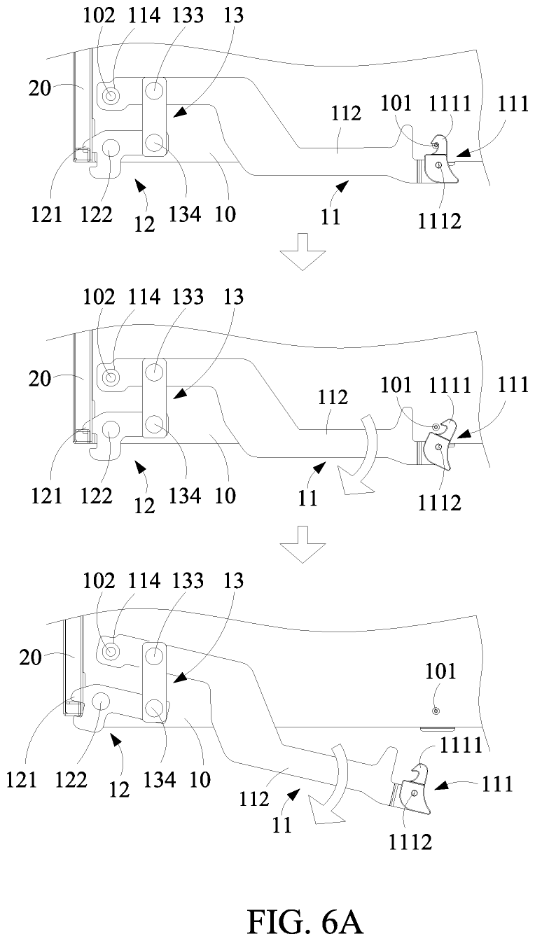

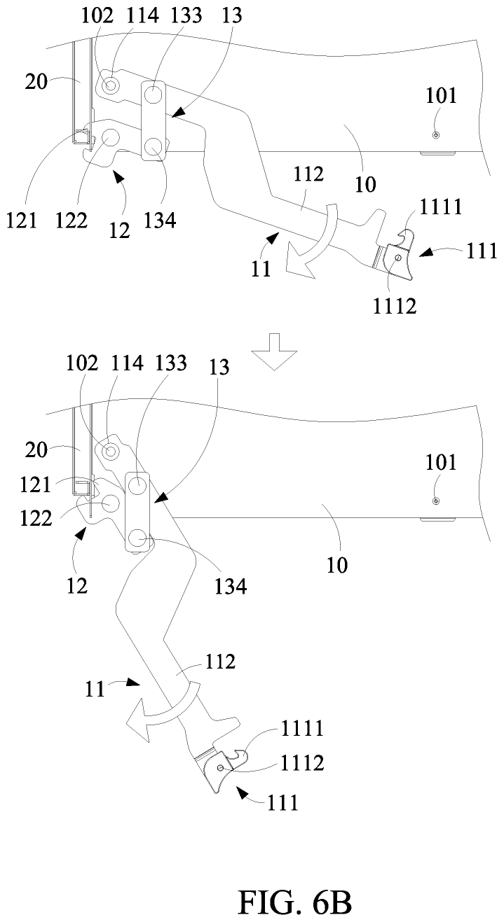

Referring to FIG. 1 through FIG. 6B, an engaging driving structure 1 of the present disclosure comprises a first driving fastener 11, a second driving fastener 12 and a linking unit 13.

The second driving fastener 12 is parallel to the first driving fastener 11.

The linking unit 13 is perpendicular to both the first driving fastener 11 and the second driving fastener 12 and is disposed therebetween. The linking unit 13 movably connects the first driving fastener 11 and the second driving fastener 12.

The process of assembling the engaging driving structure 1 involves movably attaching a first object 10 to an axle portion 102 of the first driving fastener 11 and an axle portion 102 of the second driving fastener 12. The axle portions 102 are fixed to the first object 10, adapted to allow the first driving fastener 11 and the second driving fastener 12 to rotate at fixed positions, adapted to allow the first driving fastener 11 to drive the linking unit 13 and the second driving fastener 12 under a lever force, and adapted to exert lever forces on a second object 20, thereby allowing the first object 10 and the second object 20 to undergo displacement relative to each other.

In an embodiment of the present disclosure, the first object 10 or the second object 20 is a casing, frame, housing, box, support, PCB, motherboard, server, storage, hard disk drive, heat sink, hydrocooling device, rail, plate or disc.

At the beginning of the process of use of the engaging driving structure 1, the second driving fastener 12 is engaged with a second object 20, and the first driving fastener 11 is engaged with the first object 10, allowing the engaging driving structure 1 to fit the first object 10 and the second object 20 together. To separate the second object 20 from the first object 10, the user exerts a force to move the first driving fastener 11 to not only disengage the first driving fastener 11 from the first object 10 but also link the first driving fastener 11 and the second driving fastener 12 through the linking unit 13, either allowing the second driving fastener 12 to drive the second object 20 or allowing the second driving fastener 12 to drive the second object 20 before disengaging the second driving fastener 12 from the second object 20. Therefore, the first driving fastener 11, the second driving fastener 12 and the linking unit 13 operate in conjunction with each other so that the engaging driving structure 1 is easy to use, labor-saving, and convenient.

The axle portions 102 are fixed to the first object 10 and adapted to allow the first driving fastener 11 and the second driving fastener 12 to rotate at fixed positions, adapted to allow the first driving fastener 11 to drive the linking unit 13 and the second driving fastener 12 under a lever force, and adapted to exert lever forces on the second object 20, thereby allowing the first object 10 and the second object 20 to undergo displacement relative to each other. Therefore, the first driving fastener 11, the second driving fastener 12 and the linking unit 13 operate in conjunction with each other to thereby effectuate engagement and/or disengagement, so as to render the engaging driving structure 1 easy to use, labor-saving, and convenient.

In an embodiment of the present disclosure, the first driving fastener 11 comprises a first engaging portion 111, an operating portion 112, a first fitting portion 114 and a second fitting portion 115. The first engaging portion 111 is disposed at one end of the operating portion 112. One end of the linking unit 13 movably connects to the second fitting portion 115.

To mount the first driving fastener 11 in place, the first fitting portion 114 is movably fitted to the first object 10 through the axle portion 102. To start using the engaging driving structure 1, the second driving fastener 12 is engaged with a second object 20, and the first engaging portion 111 of the first driving fastener 11 is engaged with a clasping portion 101 of the first object 10, thereby fitting the first object 10 and the second object 20 together by the engaging driving structure 1. To separate the second object 20 from the first object 10, the user exerts a force to move the operating portion 112 of the first driving fastener 11 to not only disengage the first engaging portion 111 from the clasping portion 101 of the first object 10 but also link the operating portion 112 of the first driving fastener 11 and the second driving fastener 12 through the linking unit 13, either allowing the second driving fastener 12 to drive the second object 20 or allowing the second driving fastener 12 to drive the second object 20 before disengaging the second driving fastener 12 from the second object 20. Therefore, the first driving fastener 11, the second driving fastener 12 and the linking unit 13 operate in conjunction with each other so that the engaging driving structure 1 is easy to use, labor-saving, and convenient.

In an embodiment of the present disclosure, the first engaging portion 111 has a first engaging member 1111. The first engaging member 1111 is fitted to the operating portion 112 through a pivotal connection member 1112. A resilient component 1113 is disposed between the first engaging member 1111 and the operating portion 112. Therefore, when the first engaging portion 111 is engaged with the clasping portion 101 of the first object 10, or when the first engaging portion 111 is disengaged from the clasping portion 101 of the first object 10, collaboration between the first engaging member 1111 and the pivotal connection member 1112 enables the first engaging member 1111 to undergo engagement or disengagement, whereas the resilient component 1113 enables the first engaging member 1111 to undergo engagement or disengagement and the ensuing automatic restoration to facilitate the next instance of use, so as to render the engaging driving structure 1 easy to use, labor-saving, and convenient.

In an embodiment of the present disclosure, the second driving fastener 12 comprises a second engaging portion 121, a third fitting portion 122 and a fourth fitting portion 123. The second engaging portion 121 is disposed at one end of the second driving fastener 12. The third fitting portion 122 is disposed beside the second engaging portion 121. The fourth fitting portion 123 is disposed beside the third fitting portion 122. The other end of the linking unit 13 movably connects to the fourth fitting portion 123.

The assembly process involves movably fitting the first fitting portion 114 of the first driving fastener 11 to the first object 10 through the axle portion 102 and movably fitting the third fitting portion 122 of the second driving fastener 12 to the first object 10 through the axle portion 102. To start using the engaging driving structure, the second engaging portion 121 of the second driving fastener 12 is engaged with the second object 20, and the first engaging member 1111 of the first engaging portion 111 of the first driving fastener 11 is engaged with the clasping portion 101 of the first object 10, so as for the engaging driving structure 1 to fit the first object 10 and the second object 20 together. To separate the second object 20 from the first object 10, the user exerts a force on the operating portion 112 of the first driving fastener 11 to move it and thereby disengage the first engaging member 1111 of the first engaging portion 111 from the clasping portion 101 of the first object 10, allow the operating portion 112 of the first driving fastener 11 to link to the second driving fastener 12 through the linking unit 13, allow the second engaging portion 121 of the second driving fastener 12 to drive the movement of the second object 20, or allow the second engaging portion 121 of the second driving fastener 12 to drive the movement of the second object 20 before disengaging the second driving fastener 12 from the second object 20. Therefore, the first driving fastener 11, the second driving fastener 12 and the linking unit 13 operate in conjunction with each other so that the engaging driving structure 1 is easy to use, labor-saving, and convenient.

In an embodiment of the present disclosure, a first connection portion 131 is disposed at one end of the linking unit 13, and a second connection portion 132 is disposed at the other end of the linking unit 13. The first connection portion 131 movably connects to the second fitting portion 115 of the first driving fastener 11 through a first axle portion 133. The second connection portion 132 movably connects to the fourth fitting portion 123 of the second driving fastener 12 through a second axle portion 134.

Therefore, the operating portion 112 of the first driving fastener 11 is linked to the second driving fastener 12 through the linking unit 13, whereas collaboration between the first connection portion 131, the first axle portion 133, the second connection portion 132 and the second axle portion 134 is conducive to linking the first driving fastener 11 and the second driving fastener 12 to thereby effectuate engagement and/or disengagement, so as to render the engaging driving structure 1 easy to use, labor-saving, and convenient.

In an embodiment of the present disclosure, the first axle portion 133 and the second axle portion 134 each penetrate a washer 135. Alternatively, the first axle portion 133 or the second axle portion 134 penetrates a washer 135. The washer 135 is disposed between the linking unit 13 and the first driving fastener 11 or the second driving fastener 12. The washer 135 enables the linking unit 13 in operation to attain satisfactory resistance and be abrasive-resistant.

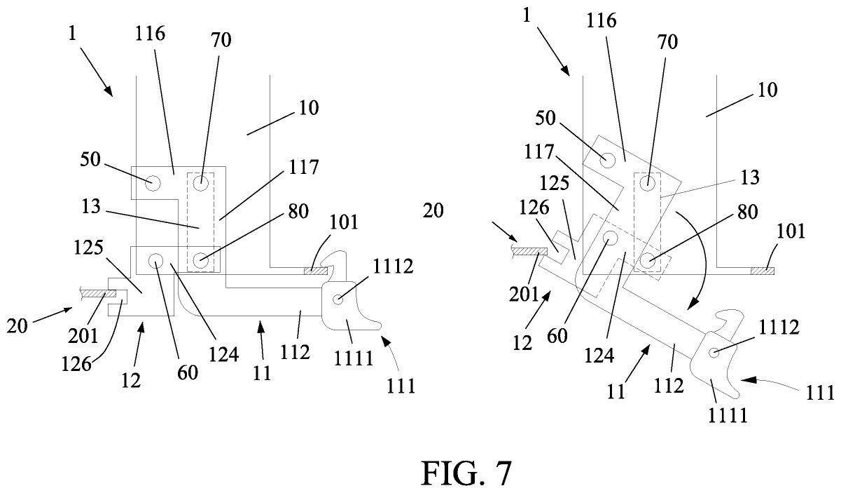

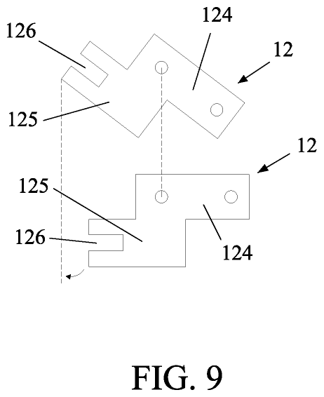

Referring to FIG. 7 through FIG. 10, the present disclosure provides an engaging driving structure 1. The engaging driving structure 1 is disposed on a first object 10 and adapted to abut against a second object 20. The engaging driving structure 1 comprises a first driving fastener 11, a second driving fastener 12 and a linking unit 13. The first driving fastener 11 is movably fitted to the first object 10. The second driving fastener 12 is movably fitted to the first object 10 and adapted to abut against the second object 20. The linking unit 13 is movably fitted between the first driving fastener 11 and the second driving fastener 12. The first driving fastener 11 is operated and linked to the second driving fastener 12 to cause movement thereof, so as for the second driving fastener 12 to abut against the second object 20.

As mentioned above, the engaging driving structure 1 of the present disclosure has advantageous technical features described below. The first driving fastener 11 is pulled to drive the movement of the second driving fastener 12 through the linking unit 13. The force exerted by the user to pull the first driving fastener 11 is much less than the thrust generated by the second driving fastener 12 to push the second object 20. Thus, the user just needs to apply a slight force in order to generate an enormous thrust. Therefore, the engaging driving structure 1 of the present disclosure is labor-saving.

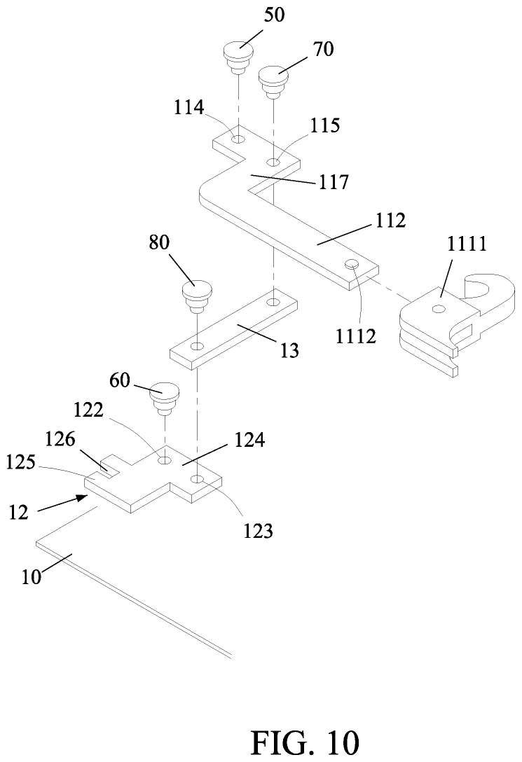

Referring to FIG. 7 and FIG. 10, in an embodiment, the terminal end of the first driving fastener 11 is movably fitted to an engaging member 1111. The first object 10 comprises a clasping portion 101 corresponding in position to the engaging member 1111. The engaging member 1111 is engaged with the clasping portion 101, such that the second driving fastener 12 and the second object 20 abut against each other until they are positioned in place. Preferably, the clasping portion 101 is a flange which extends outward from a side of the first object 10, and the side of the first object 10 is positioned distal to the second object 20. The engaging member 1111 is movably fitted in place, for example, by pivotally connecting the pivotal connection member 1112 to a hook of the first driving fastener 11. However, the present disclosure is not limited thereto.

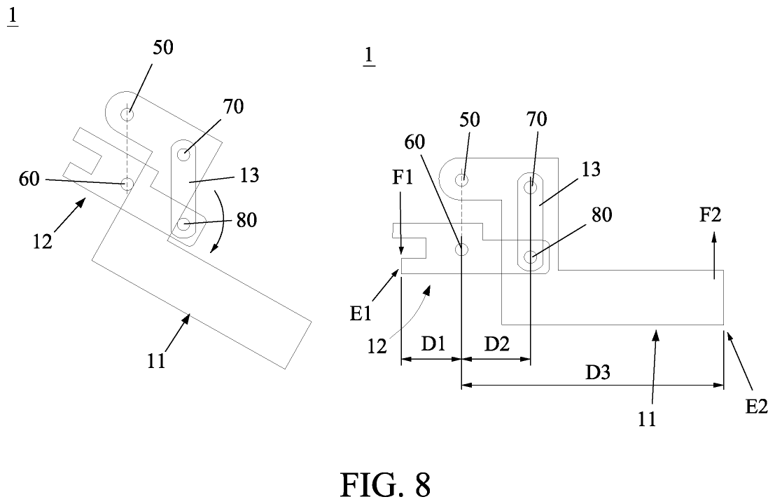

Referring to FIG. 7 through FIG. 10, in an embodiment, the first driving fastener 11 pivotally connects to the first object 10, the second driving fastener 12 to the first object 10, and the linking unit 13 to the first driving fastener 11 and the second driving fastener 12. The first driving fastener 11 comprises a movable fitting portion 116 movably fitted to the first object 10 and the linking unit 13, an operating portion 112 parallel to the movable fitting portion 116, and a connection portion 117 connected between the movable fitting portion 116 and the operating portion 112. The second driving fastener 12 comprises a movable fitting body 124 and an abutting portion 125 connected to the movable fitting body 124. The movable fitting body 124 is movably fitted to the first object 10 and the linking unit 13. The abutting portion 125 has a dent portion 126 for receiving a flange 201 of the second object 20. However, the present disclosure is not limited thereto. The linking unit 13 is a connecting rod. The two terminal ends of the linking unit 13 are movably fitted to the first driving fastener 11 and the second driving fastener 12, respectively. Preferably, in this embodiment, the engaging driving structure 1 further comprises a first pivot 50, a second pivot 60, a third pivot 70 and a fourth pivot 80. The first pivot 50 and the first fitting portion 114 allow the first driving fastener 11 to pivotally connect to the first object 10. The third pivot 70 and the second fitting portion 115 allow the first driving fastener 11 to pivotally connect to the linking unit 13. The second pivot 60 and the third fitting portion 122 allow the second driving fastener 12 to pivotally connect to the first object 10. The fourth pivot 80 and the fourth fitting portion 123 allow the second driving fastener 12 to pivotally connect to the linking unit 13. The third pivot 70 pivotally connects the linking unit 13 to the first driving fastener 11. The fourth pivot pivotally connects the linking unit 13 to the second driving fastener 12. Referring to FIG. 8, the first pivot 50, the second pivot 60, the third pivot 70 and the fourth pivot 80 are arranged to form a rectangle, not only allowing the engaging member 1111 to engage with the clasping portion 101, but also allowing the second driving fastener 12 and the second object 20 to abut against each other until they are positioned in place. Alternatively, the first pivot 50, the second pivot 60, the third pivot 70 and the fourth pivot 80 are arranged to form a parallelogram, exclusive of a rectangle, and thereby allow the engaging member 1111 to separate from the clasping portion 101, with the second driving fastener 12 abutting against the second object 20.

Referring to FIG. 7 and FIG. 8, an abutting-oriented acted point E1 is located between the second driving fastener 12 and the second object 20. The acted point E1 is spaced apart from the first pivot 50 and the second pivot 60 by a distance D1. The distance between the first pivot 50 and the third pivot 70 is denoted by D2. The distance between the second pivot 60 and the fourth pivot 80 is denoted by D2. The first driving fastener 11 has an acting point E2. The acting point E2 is spaced apart from the first pivot 50 and the second pivot 60 by a distance D3, where 0.08<D1/D3<0.12, 0.15<D2/(D3−D2)<0.3. The composite abutting force of the acted point E1 is denoted by F1, and the applied force of the acting point E2 is denoted by F2. According to the principle of torque, applied force F2 and abutting force F1 satisfy the relation: 0.012≤F1/F2≤0.036. Thus, the applied force F2 required by the acting point E2 is much less than the abutting force F1 generated by the acted point E1.

Referring to FIG. 7, the first object 10 is a frame back plate, whereas the second object 20 is a target device, such as a hard disk drive, expansion card, and circuit board. However, the present disclosure is not limited thereto.

While the present disclosure has been described by means of specific embodiments, numerous modifications and variations could be made thereto by those skilled in the art without departing from the scope and spirit of the present disclosure set forth in the claims.

What is claimed is:

1. An engaging driving structure, comprising:
a first driving fastener;
a second driving fastener; and
a linking unit disposed between the first driving fastener and the second driving fastener and adapted to movably connect the first driving fastener and the second driving fastener.

2. An engaging driving structure, comprising:
a first driving fastener movably fitted to a first object;
a second driving fastener movably fitted to the first object and adapted to abut against a second object; and
a linking unit movably fitted between the first driving fastener and the second driving fastener,
wherein the first driving fastener is operated and linked to the second driving fastener to cause movement thereof, so as for the second driving fastener to abut against the second object.

3. The engaging driving structure of claim 1, wherein the first driving fastener comprises a first engaging portion, an operating portion, a first fitting portion and a second fitting portion, with the first engaging portion disposed at the first driving fastener.

4. The engaging driving structure of claim 1, wherein the first driving fastener comprises a first fitting portion and a second fitting portion, with the first fitting portion movably fitted to a first object, and the linking unit movably connects to the second fitting portion.

5. The engaging driving structure of claim 1, wherein the first driving fastener comprises a first engaging portion and an operating portion, with the first engaging portion having a first engaging member, and the first engaging member is fitted to the first driving fastener through a pivotal connection member, and a resilient component is disposed between the first engaging member and the first driving fastener.

6. The engaging driving structure of claim 1, wherein the second driving fastener comprises a second engaging portion, a third fitting portion and a fourth fitting portion, with the second engaging portion disposed at the second driving fastener, the third fitting portion disposed at the second engaging portion, and the fourth fitting portion disposed at the third fitting portion.

7. The engaging driving structure of claim 1, wherein the second driving fastener comprises a second engaging portion, and the second engaging portion is engaged with a second object.

8. The engaging driving structure of claim 1, wherein the second driving fastener comprises a third fitting portion and a fourth fitting portion, with the third fitting portion movably fitted to a first object, and the linking unit movably connects to the fourth fitting portion.

9. The engaging driving structure of claim 1, wherein the linking unit has a first connection portion, and the first connection portion is movably connected to the first driving fastener by a first axle portion, and the linking unit has a second connection portion, and the second connection portion is movably connected to the second driving fastener by a second axle portion.

10. The engaging driving structure of claim 1, wherein the first driving fastener and the second driving fastener each have an axle portion, and the axle portions are fixed to a first object to allow the first driving fastener and the second driving fastener to rotate at fixed positions, allow the first driving fastener to drive the linking unit and the second driving fastener under a lever force, exert lever forces on a second object, and allow the first object and the second object to undergo displacement relative to each other.

11. The engaging driving structure of claim 2, wherein the first driving fastener is movably fitted to an engaging member, and the first object comprises a clasping portion corresponding in position to the engaging member, wherein the engaging member is engaged with the clasping portion, such that the second driving fastener and the second object abut against each other until they are positioned in place.

12. The engaging driving structure of claim 2, further comprising a first pivot, a second pivot, a third pivot and a fourth pivot, wherein the first pivot pivotally connects the first driving fastener to the first object, the second pivot pivotally connects the second driving fastener to the first object, the third pivot pivotally connects the linking unit to the first driving fastener, and the fourth pivot pivotally connects the linking unit to the second driving fastener.

13. The engaging driving structure of claim 2, wherein the first driving fastener comprises a movable fitting portion movably fitted to the first object and the linking unit, an operating portion parallel to the movable fitting portion, and a connection portion connected between the movable fitting portion and the operating portion.

14. The engaging driving structure of claim 2, wherein the second driving fastener comprises a movable fitting body and an abutting portion connected to the movable fitting body, with the movable fitting body movably fitted to the first object and the linking unit.

15. The engaging driving structure of claim 1, wherein the linking unit is a connecting rod, and two terminal ends of the linking unit are movably fitted to the first driving fastener and the second driving fastener, respectively.
